(19) United States
(12) Patent Application Publication
(10) Pub. No.: US 2001/0050221 A1
(43) Pub. Date: Dec. 13, 2001

(54) Method for manufacturing infrared ray detector element

(76) Inventors: Hiroko Higuma, Tokyo (JP); Shoji Miyashita, Tokyo (JP); Fusaoki Uchikawa, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/765,384

(22) Filed: Jan. 22, 2001

(30) Foreign Application Priority Data
Apr. 26, 2000 (JP) 2000-125709

(51) Int. Cl. C23C 14/32

(52) U.S. Cl. 204/192.21; 204/192.22

(57) ABSTRACT

A method for manufacturing an infrared ray detector element utilizing a bolometer thin film having Bi₁₋ₓAₓMn₁O₃ (element A being at least one element selected from a rare earth metal or an alkaline earth metal, 0≦x<1) as a main component. The method comprises a step of forming an oxide thin film having a metallic composition of Bi:A:Mn=1−x:X:1 by sputtering at a substrate temperature of equal to or above 100° C. and less than 500° C. within a gas atmosphere of containing oxygen or ozone. The second step is applying a heat treatment to the oxide thin film within a gas atmosphere containing oxygen or ozone to reduce the volume resistivity of the oxide thin film to a level at which an infrared ray detector circuit can operate. Thus, the bolometer having Bi₁₋ₓAₓMn₁O₃ as a main component can be functioned as a bolometer and an infrared ray detector element of a high detectivity can be put in mass-production.

### CROSS REFERENCE TO RELATED APPLICATION

This application is based on Application No. 2000-125709, filed in Japan on Apr. 26, 2000, the contents of which are hereby incorporated by reference.

### BACKGROUND OF THE INVENTION

This invention relates to a method for manufacturing an infrared ray detector element and, more particularly, to a method for manufacturing an infrared ray detector element which is to be utilized as two-dimension image sensor with a plurality of elements arranged on a two-dimensional plane and, still more particularly, to a method for manufacturing a un-cooled infrared ray detector element of the type in which the temperature change is caused by absorbing an incoming infrared ray and the radiation intensity of the infrared ray is read as a signal through the use of a material of which resistivity is changed according to the temperature change.

The infrared ray detector includes a thermal detector such as bolometer system and a photon type detector. The photon type detector must be cooled close to the temperature of liquid nitrogen to decrease the noise due to the dark current in order to increase the detection sensitivity. On the other hand, bolometer type infrared ray detector needs not be cooled, so that it is very advantageous in cost decrease, simplification and compactness of the device as well as the portable use.

The bolometer type infrared ray detector element is of the type in which the temperature change is caused at the light-receiving portion by absorbing an incoming infrared ray and the radiation intensity of the infrared ray is read as an electrical signal through the use of a material of which resistivity is changed according to the temperature change. Therefore, the greater the temperature dependence of the resistance (the temperature coefficient of resistance: TCR), the higher the detectivity. As for the bolometer used in the bolometer type un-cooled infrared ray detector or of the type in which the resistance changes according to the temperature change when the infrared ray is absorbed at room temperature, Si, Ge or V₂O₃ which is a semiconductor material has heretofore been used. However, the TCFR of Si thin film is as small as 1.5%/deg. or so and even the TCR of the V₂O₃ thin film which is relatively high in the sensitivity is of the order of 2.0%/deg.

A recently proposed infrared ray detector uses the perovskite type Mn oxide known as La₁₋ₓSrₓMn₃ (0<x<1) as a bolometer of the thin film. The TCR of La₁₋ₓSrₓMn₃ is greater than 3.0%/deg. at or below 0° C. and is of the order of 2.5%/deg. at room temperature. This technique is disclosed in Japanese Patent Laid-Open No. 10-163510.

Also, the inventors of the present invention have already proposed an infrared ray detector which uses the perovskite type Mn oxide known as Bi₁₋ₓAₓMn₁O₃ (0≦x<1, A is at least one kind of metal selected from rare earth metals and the alkaline earth metals) as a bolometer of the thin film. As for the TCR of Bi₁₋ₓAₓMn₁O₃ as a main composition for the room temperature, the one within the range of from 3.0%/deg. to 4.0%/deg. is obtained. This technique is disclosed in Japanese Patent Laid-Open No. 10-307324. Thus, Bi₁₋ₓAₓMn₁O₃ in particular out of the perovskite type Mn oxides is a very effective material for obtaining a high detectivity of infrared ray detector element because it is high in the TCR at room temperature.

In order to realize the high detectivity of the un-cooled infrared ray detector element, improvement of the performance of the bolometer is necessary and it is necessary to increase the TCR at room temperature to be equal to or more than 2.5%/deg. and preferably equal to or more than 3.0%/deg. As discussed above, Bi₁₋ₓAₓMn₁O₃ (0≦x<1, element A is at least one kind of metal selected from rare earth metals and the alkaline earth metals) is high in the TCR at room temperature, so that it is expected to be a good candidate for the bolometer as the thin film, there were no manufacturing method for the thin film containing Bi₁₋ₓAₓMn₁O₃ as a main composition and superior in mass productivity.

On the other hand, in the infrared ray detector element, base metals or compositions easily oxidized or low-melting point metals are used as the materials for wiring and electrodes and they are embedded within the Si substrate as a read-out circuit, and the bolometer is formed on a structure member which is an SiO₂ layer disposed on the Si substrate through the air gap portion. Therefore, the bolometer must be formed at a substrate temperature equal to or less than 500° C., that is, the substrate temperature lower than the that the wiring and the electrodes do not oxide or melt.

The present invention has been made in order to solve the above discussed problems and has as its object the provision of a method for manufacturing, in mass-production, an infrared ray detector element utilizing a high detectivity bolometer at a low substrate temperature less than 500° C. and preferably equal to or less than 450° C. with a thin film material having a high temperature coefficient of resistance.

### SUMMARY OF THE INVENTION

With the above objects in view, the present invention resides in a method for manufacturing an infrared ray detector element utilizing a bolometer as thin film having Bi₁₋ₓAₓMn₁O₃ (element A being at least one element selected from a rare earth metal or an alkaline earth metal, 0≦x<1) as a main component. The method comprises a step of forming a thin film of an oxide having a metallic composition of Bi:A:Mn=1−x:X:1 by sputtering at a substrate temperature of equal to or above 100° C. and less than 500° C. within a gas atmosphere of containing oxygen or ozone, and a step of applying a heat treatment to the oxide thin film within a gas atmosphere containing oxygen or ozone to reduce the volume resistivity of the oxyde thin film to a level at which an infrared ray detector circuit can operate.

The oxide thin film may be laminated on a structure member which is an SiO₂ layer disposed on an Si substrate through an air gap or on an electrical insulator layer laminated on it.

The heat treatment applying to the oxide thin film may be achieved by an infrared ray or a laser irradiation.

The heat treatment applying to the oxide thin film may comprise a step of maintaining the oxide thin film at a temperature of 380° C.-450° C. for 10 min.-15 min.

The level of the volume resistivity of the oxide thin film at which the infra-read ray detector circuit can operate may be equal to or more than 3.0 Ωcm.

Thus, according to the manufacturing method of an infrared ray detector element of the present invention, the method comprises the step of forming an oxide thin film as bolometer having a metallic composition of Bi:A: Mn=1−x:X:1 by sputtering at a substrate temperature of equal to or above 100° C. and less than 500° C. within a gas atmosphere of containing oxygen or ozone, and the step of applying a heat treatment to the thin film within a gas atmoshpere containing oxygen or ozone to reduce the volume resistivity of the thin film of oxide to a level at which an infrared ray detector circuit can operate, whereby a thin film having Bi₁₋ₓAₓMn₁O₃ (element A being at least one element selected from a rare earth metal or an alkaline earth metal, 0≦x<1) as a main component is caused to function as a bolometer.

According to the method for manufacturing an infrared ray detector element of the present invention, the thin film having Bi₁₋ₓAₓMn₁O₃ (element A being at least one element selected from a rare earth metal or an alkaline earth metal, 0≦x<1) as a main component is laminated on a structure member which is an SiO₂ layer disposed on an Si substrated through an air gap or on an electrical insulator layer laminated on a structure member which is an SiO₂ layer disposed on an Si substrated through an air gap.

According to the method for manufacturing an infrared ray detector element of the present invention, the oxide thin film having a metallic composition of Bi:A:Mn=1−x:X:1 heat treated by an infrared ray or a laser irradiation within a gas atmosphere of containing oxygen or ozone, whereby the volume resistivity of the oxide thin film to a level at which an infrared ray detector circuit can operate, whereby a thin film having Bi₁₋ₓAₓMn₁O₃ (element A being at least one element selected from a rare earth metal or an alkaline earth metal, 0≦x<1) as a main component is caused to be able to function as a bolometer. According to the method for manufacturing an infrared ray detector element of the present invention, the main component of the oxide thin film of which resistivity changes according to the temperature is Bi₁₋ₓAₓMn₁O₃ (element A being at least one element selected from a rare earth metal or an alkaline earth metal, 0≦x<1), and this oxide thin film exhibiting a semiconductor-like electrical conductivity and has a high temperature coefficient of resistance at a temperature range around the room temperature. The thin film of Bi₁₋ₓAₓMn₁O₃ having a high temperature coefficient of resistance at this semiconductor range can be used as the bolometer, by providing which, the infrared ray detector element is to be made high detectivity.

Also, by arranging a plurality of elements on a two-dimensional plane, a high-detectivity two-dimensional image sensor can be obtained.

### BRIEF DESCRIPTION OF THE DRAWINGS

The present invention will become more readily apparent from the following detailed description of the preferred embodiments of the present invention taken in conjunction with the accompanying drawings, in which:

FIG. 1 is an explanatory sectional view showing the structure of the light receiving portion of the infrared ray detector element according to the first embodiment of the method for manufacturing an infrared ray detector element of the present invention;

FIG. 2 is a perspective view showing the structure of the light receiving portion of the infrared ray detector element according to the first embodiment of the method for manufacturing an infrared ray detector element of the present invention;

FIG. 3 is a perspective view showing the tool for measuring the electric resistance used in the infrared ray detector element of the present invention;

FIG. 4 is a graph showing relationship between the temperature coefficient of resistance and the temperature of the first and the second embodiments of the method for manufacturing an infrared ray detector element of the present invention;

FIG. 5 is a explanatory sectional view showing the structure of the light-receiving portion of the infrared ray detector element according to the second embodiments of the method for manufacturing an infrared ray detector element of the present invention;

FIG. 6 is a schematic diagram showing the structure of the heat treatment device for the infrared ray radiation used in the fourth embodiment of the method for manufacturing an infrared ray detector element of the present invention;

FIG. 7 is a graph showing the relationship between the resistivity of the infra-read ray detector element and the time for maintaining the substrate surface temperature at 500° C. according to the fourth embodiment of the method for manufacturing an infrared ray detector element of the present invention; and

FIG. 8 is a schematic diagram showing the structure of the heat treatment device for the laser radiation used in the fifth embodiment of the method for manufacturing an infrared ray detector element of the present invention.

### DESCRIPTION OF THE PREFERRED EMBODIMENTS

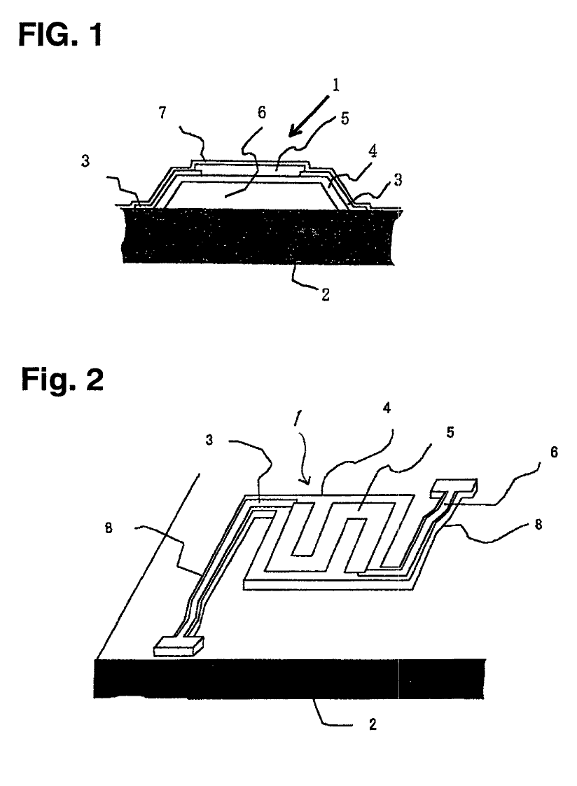

FIGS. 1 is an explanatory sectional view of the infrared ray detector element according to the first embodiment of the present invention. The light-receiving portion 1 of the infrared ray detector element is formed on a bridge structure member 4 made of an SiO₂ layer and defining an air gap portion 6 for thermal insulation, the bridge structure member 4 being formed on a silicon substrate 2. The SiO₂ layer is formed by the plasma CVD. Wiring 3 of Pt on the SiO₂ layer extends along support legs of the bridge structure member 4 to the substrate 2 and a bolometer 5 is provided on the SiO₂ layer and a portion of the Pt wiring. The infrared detector circuit has the light-receiving portion 1 that changes the temperature by absorbing the infrared ray and changes the resistance of the bolometer 5, and this resistance change is detected by applying a bias voltage from the ends of the wiring 3 positioned under the bolometer of thin film 5.

According to the first embodiment of the present invention, the main composition of the bolometer of the oxide thin film is Bi₁₋ₓAₓMn₁O₃, where A is La and Sr and x=0.4. That is, Bi_{0.6}Sr_{0.3}La_{0.1}MnO₃. This thin film is manufactured by maintaining the substrate temperature at 430° C. within a chamber in which a gas of 100% oxygen is introduced and gas pressure is regulated at 0.5 Pa to form an oxide thin film having a metallic composition of Bi:Sr:La:Mn=0.6:0.3:0.1 by the sputtering, then it is held at 430° C. at a higher gas pressure of 3 Pa for 15 min. and cooled to room temperature at a rate of about 10° C./min. After the bolometer of thin film has been formed, the outermost layer of the light-receiving portion 1 is coated with a protective film 7.

FIG. 2 is a perspective view of the infrared ray detector element according to the first embodiment of the present invention. In this figure, the protective film 7 is not illustrated. The support legs 8 of the bridge structure are elongated in order to increase the thermal insulation of the light-receiving portion 1. The light-receiving portion 1 is patterned. The structure and the configuration of the infrared ray detector element and its peripheral portion shown and described in conjunction with this embodiment are only an example of the present invention and do not mean that the present invention is limited to this embodiment.

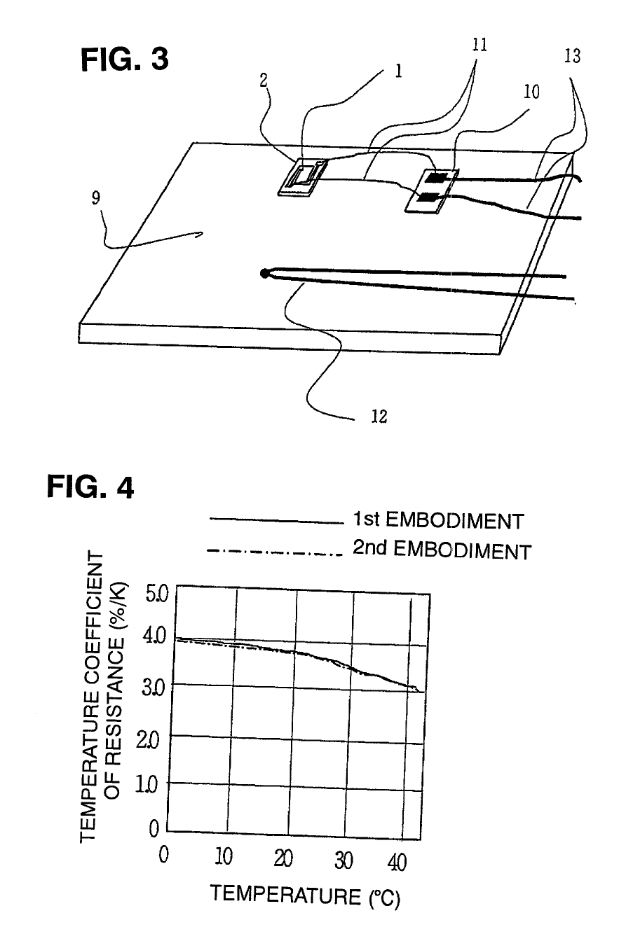

The electrical resistance was measured by a measuring device shown in FIG. 3. In this figure, the silicon substrate 2 which is the infrared ray detector element is attached to the base plate 9 by A on Alpha (a trade name) and the electrode pad 10 and the element are connected by wire bonding 11, and the current conduction test was achieved by connecting a current lead 13 to the electrode pad 10. Also, a temperature sensor 12 is attached to the base plate 9 in a similar manner to the element by the same bonding agent. The current value is adjusted so that it is 3.5V at 30° C. and a constant current is supplied and the electrical resistance was measured by the direct current 2 terminal method. The measurement of the temperature coefficient of resistance of the Bi_{0.6}Sr_{0.3}La_{0.1}MnO₃ thin film was carried out by placing the measuring device within a constant temperature tank and calculated based on the measured resistance values at various temperatures. FIG. 4 illustrates the relationship between the temperature coefficient of resistance and the temperature, from which it is seen that a high temperature coefficient of resistance equal to or higher than 3.0%/K can be obtained even at a temperature lower than 30° C., at which temperature the volume resistivity is 3.0 Ωcm.

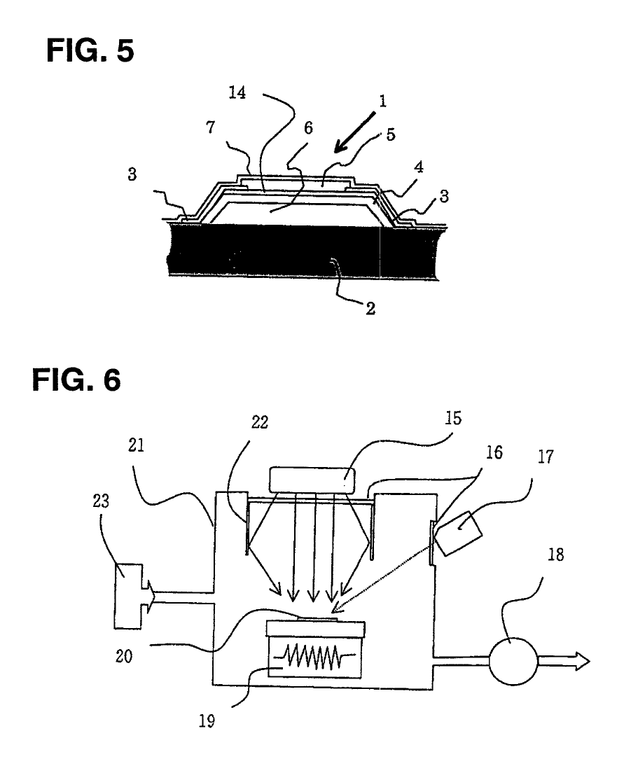

FIG. 5 is an explanatory sectional view of the infrared ray detector element associated with the second embodiment of the present invention. The light-receiving portion 1 of the infrared ray detector element comprises a thermal insulator gap 6 defined by the bridge structure member 4 of the oxide silicon layer on the silicon substrate 2. The bridge structure member 4 has two layer structure in which An electrically insulating layer 14 made of a YSZ layer is laminated on the bridge structure member 4 made of the SiO₂ layer. This embodiment is similar to the first embodiment except that there is an electrically insulating layer 14.

The SiO₂ layer was formed by the plasma CVD in a manner similar to that of the first embodiment. The YSZ layers was formed by electron beam vapor deposition. The main composition of the bolometer of thin film is Bi_{0.6}Sr_{0.3}La_{0.1}MnO₃. The Bi_{0.6}Sr_{0.3}La_{0.1}MnO₃ thin film was manufactured by a method similar to that of the first embodiment except that the sputtering was carried out at a substrate temperature of 410° C. and that the thin film is maintained for 15 min. at the substrate temperature of 410° C. after the sputtering.

The measurement of the electrical resistance and the calculation of the temperature coefficient of resistance were achieved in a similar manner as in the first embodiment. FIG. 4 illustrates the relationship between the temperature coefficient of resistance and the temperature of the first embodiment and the second embodiment. In the first embodiment, the resistivity at 30° C. is 3.0 Ωcm and from FIG. 4 that a high temperature coefficient of resistance equal to or higher than 3.0%/K can be obtained even at a temperature lower than 30° C. in the first embodiment. Also, in the second embodiment, as apparent from FIG. 4, a high temperature coefficient of resistance equal to or higher than 3.0%/K can be obtained even at a temperature lower than 30° C. The volume resistivity at 30° C. is 3.0 Ωcm in the first embodiment and 1.6 Ωcm in the second embodiment. In the first and the second embodiments, the composition of the bolometer thin film is the same Bi_{0.6}Sr_{0.3}La_{0.1}MnO₃, but in the second embodiment, the volume resistivity was low even though the substrate temperature was lower than that of the first embodiment by 20° C. The study of the crystal of the oxide thin film bolometer by the X-ray diffraction revealed that the film of the second embodiment that is formed on the YSZ is more intensive than the first embodiment and the crystal property is increased. From the above, the bolometer thin film of the first and the second embodiments can be formed by the sputtering or the heat treatment at a substrate temperature equal to or less than 500° C., and they have a high temperature coefficient of resistance of 3.0%/K even at a temperature lower than 30° C. or more and the volume resistivity of the level that can operate the infrared ray detector circuit.

Although the YSZ has been described as an embodiment of the electrical insulating layer of the second embodiment, with MgO, Al₂O₃, Y₂O₃, CeO₂,HfO₂, or the like can be used with similar good results though the present invention is not to be limited to these material.

According to the third embodiment of the present invention, the main composition of the oxide thin film for bolometer is Bi₁₋ₓAₓMn₁O₃, where A is Sr and x=0.4. That is, Bi_{0.6}Sr_{0.3}La_{0.1}MnO₃. This thin film is manufactured by first forming an oxide thin film having a metallic composition of Bi:Sr::Mn=0.6:0.4:0.1 by the sputtering on a silicon oxide layer. The sputtering conditions were constant 0.8 Pa gas pressure and the kinds of gas and the substrate temperature were changed. The gas (A) was ozone 100%, gas (B) was oxygen 100%, gas (C) was a mixture of ozone 400% and argon 60%, gas (D) was a mixture of oxygen 40% and argon 60% and gas; (E) was argon 100% for comparison.

After forming the oxide thin film having a metallic composition of Bi:Sr:Mn=0.6:0.4:0.1 by the sputtering, the same temperature as that during the sputtering was maintained for 10 minutes under the gas pressure of 4 Pa and then gradually cooled to room temperature at a rate of 10° C./min. to obtain various thin films (A) to (D) and a film (E) for comparison. Also, a comparison sample (F) was made by forming by sputtering with the gas (A) an oxide thin film having a metallic composition of Bi:Sr:Mn=0.6:0.4:0.1 and immediately cooled to room temperature at a rate of 10° C./min. and a comparison sample (G) was made by forming by sputtering with the gas (D) a thin film having a composition of Bi:Sr:Mn=0.6:0.4:0.1 and immediately cooled to room temperature at a rate of about 1° C./min.

Before the oxide thin film were patterned for bolometers and protective film were coated, the electrical conductivity of the surfaces of the thin films of the present invention formed under the above various conditions as well as the comparison films were checked by a tester. Table 1 shown the results. In Table 1, symbol ◯ represents the piece that has the surface resistance of equal to or less than 2MΩ and the tester check result was conductive, symbol X represents the one that has the element resistance of more than 2MΩ and the tester check result was non-conductive and symbol − represents the one that the electrode came off so that forming condition is not preferable.

TABLE 1
Relationship between Temperature and Conductivity

| | substrate temperature | | | | | | |
|---|---|---|---|---|---|---|---|
| | 300° | 380° | 400° | 450° | 500° | 550° | 600° |
| gas/cooling conditions | C. | C. | C. | C. | C. | C. | C. |
| film (A) (invention) | X | ◯ | ◯ | ◯ | ◯ | — | — |
| film (B) (invention) | X | X | ◯ | ◯ | ◯ | — | — |
| film (C) (invention) | X | X | ◯ | ◯ | ◯ | — | — |
| film (D) (invention) | X | X | X | ◯ | ◯ | — | — |
| sample (E) | X | X | X | X | X | — | — |
| sample (F) | X | X | X | X | X | — | — |
| sample (G) | X | X | X | X | ◯ | — | — |

As apparent from Table 1, the oxide thin film according to the present invention manufactured by being formed by sputtering using a gas containing oxygen or ozone and heat treated within the atmosphere containing oxygen or ozone exhibited electrical conductivity at a substrate temperature of equal to or lower than 450° C. The film (E) that did not use the gas containing no oxygen or ozone did not exhibit conductivity. The film (F) or the film (G) that did not heat-treated within the atmosphere containing oxygen or ozone after the sputtering formation using the gas containing oxygen or ozone did not exhibit electrical conductivity or an electrically conductive thin film was obtained at or above 500° C. Next after ptterning of the bolometer, the electrical resistance at 30° C. was measured for the bolometer thin films (A) to (D) and good results were obtained as a volume resistivity of 1.00 Ωcm and a temperature coefficient of resistance of 3.0%/K for the film (A), a volume resistivity of 2.0 Ωcm and a temperature coefficient of resistance of 3.2%/K for the film (B), a volume resistivity of 3.0 Ωcm and a temperature coefficient of resistance of 3.4%/K for the film (C), and a volume resistivity of 4.0 Ωcm and a temperature coefficient of resistance of 3.6%/K for the film (D).

The time for applying the heat treatment with the gas containing oxygen or ozone after forming by sputtering the oxide thin film of Bi:Sr:Mn=0.6:0.4:0.1 is dependent upon the temperature and only five minutes are sufficient to obtain an electrically conductive film. However, the substrate temperature should be made as low as possible in order to obtain a stable film, the heat treatment time is preferably set to equal to or more than 10 minutes particularly at a temperature close to the lower temperature limit.

The infrared ray detector element of the fourth embodiment of the present invention has the similar arrangement to the first embodiment except for the main compositions of the bolometer of the thin film. The main composition of the bolometer of this embodiment is Bi₁₋ₓAₓMn₁O₃, where A is La and Sr and x=0.4. That is, Bi_{0.333}Sr_{0.333}La_{0.333}MnO₃. An oxide thin film that has a metallic main composition of Bi:Sr:La:Mn=0.333:0.333:0.333 by the sputtering and the heat treatment was manufactured under the conditions identical to that of the first embodiment. However, the electrical resistance of the oxide thin film of which metallic composition ratio is Bi:Sr:La:Mn=0.333:0.333:0.333 was as high as exceeding the measurement range of the tester used and found to be not suitable to use in infrared ray detector element. Investigation of the crystal structure of the thin film by the X-ray diffraction revealed that the perovskite structure was not presented. Therefore, after the oxide thin film of which metallic composition ratio is Bi:Sr:La:Mn=0.333:0.333:0.333 was formed under the same conditions as that of the first embodiment, the substrate temperature was increased to at 500° C. maintained it within an atmosphere of oxygen gas of 3 Pa for 5 minutes and heater was deenergized to naturally cool to at 400° C. and it took 20 minutes. Below 400° C., the heater was controlled so that the temperature gradually decrease at a rate of at 10° C./min. The tester check of the surface of this thin film exhibited 100KΩ and the volume resistivity appears to reach to a level sufficiently applicable as the bolometer thin film, but the electrode member was partially come off together with the wiring member. Such the coming off is considered due to the oxidization of the wiring member.

Then, an oxide thin film of which metallic composition ratio is Bi:Sr:La:Mn=0.333 :0.333 :0.333 was formed under the same sputtering conditions as those of the first embodiment and the substrate was immediately cooled slowly at a rate of at 10° C./min. and the film took out was subjected to the heat treatment with the heat-treatment apparatus utilizing the infrared ray lamp shown in FIG. 6 with the substrate temperature of 430° C. and within an atmosphere of oxygen gas pressure of 3 Pa.

FIG. 6 is a view showing the structure of the heat-treatment apparatus utilizing the heating by an infrared ray lamp. In the figure, the infrared ray generated by an infrared ray lamp 15 passes through the infrared ray window 16 to irradiate the substrate 20 heated to 400° C. on the resistance heating heater 19. Within chamber 21, a reflection mirror 22 is disposed to increase the energy concentration and a gas pressure of 3 Pa is maintained by the oxygen gas supply from the gas bomb 23 and a vacuum pump 18. The substrate temperature is monitored by an infrared ray camera 17.

The lamp was being power-regulated so that the source temperature of the substrate becomes 500° C. by the irradiation of the infrared ray, and the temperature was maintained by turning on and off of the lamp. The temperature was set so that the substrate surface temperature becomes 430° C. by the resistance heating heater alone. After the turning on of the lamp, the surface temperature of the substrate reached 500° C. within 10 seconds. The elements of differing temperature holding time having the temperature holding time of equal to or less than 5 minutes at 500° C. were prepared. After 5 min. irradiation of infrared ray, no change was observed in the heater temperature and the heater power control. After the lamp was deenergized, the surface temperature of the elements which were held at the temperature returned to 430° C. within several seconds and they were slowly cooled at a rate of at 10° C./min. to room temperature by the heater control.

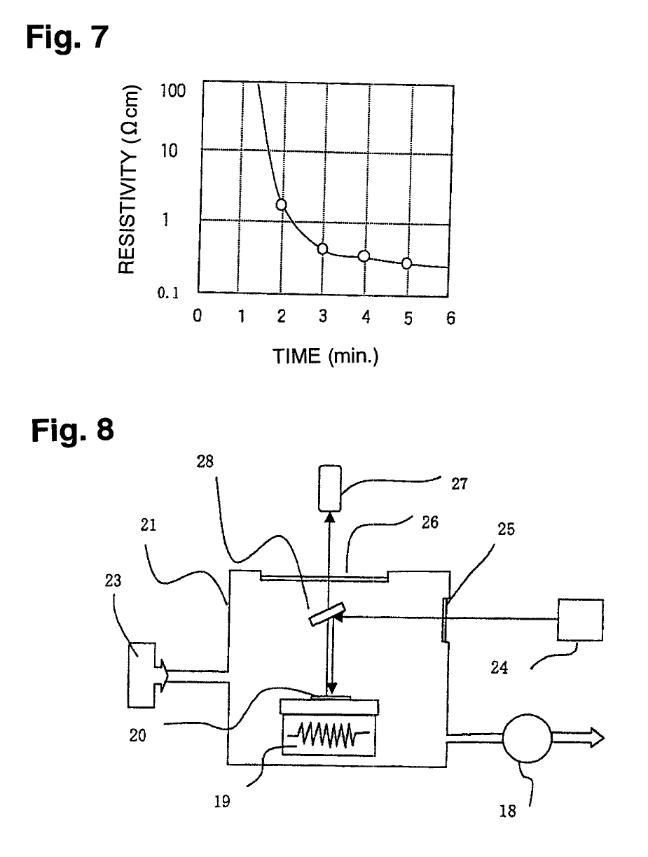

In each element heat-treated by the infrared ray irradiation, there was observed no separation of the electrode and no problem was posed in measuring the electrical resistance. The reason for this is considered to be attributable to the fact that the heat treatment through the substrate surface permits quick heating and cooling, resulting in an efficient heating of the surface, so that the temperature of the whole element is not elevated, whereby the damages to the wiring are minimized. FIG. 7 is a graph showing the relationship between the volume resistivity of the element and the time within which the temperature was held at 500° C. From the graph, it is understood that, within 2 minutes after the element is held at 500° C., that is, within 5 minutes after the lamp was energized, the resistivity was decreased as low as close to 1 Ωcm, leading to a practical level sufficiently applicable as a bolometer.

According to the fifth embodiment of the present invention, an oxide thin film of which metallic composition ratio is Bi:Sr:La:Mn=0.333:0.333:0.333 was formed under the same sputtering conditions as those of the fourth embodiment and the substrate was immediately cooled slowly at a rate of at 10° C./min. and took out. Since this thin film is not conductive as described in conjunction with the fourth embodiment, the thin film was subjected to the heat treatment under the conditions of the oxygen pressure of 3 pa, the substrate temperature of 430° C. and the thin film was repeatedly irradiated by a KrF excimer laser for 5 minutes at 50 Hz and 30W. FIG. 8 is a view showing the structure of the heat treatment apparatus utilizing the laser irradiation. In the figure, the laser beam generated by the laser beam source 24 passes through the laser beam window 25 into a chamber 21, reflects at a laser reflecting mirror 28 to irradiate the substrate 20 heated to 400° C. on the resistance heating heater 19. Within chamber 21, a gas pressure of 3 pa is maintained by the oxygen gas supply from the gas bomb 23 and a vacuum pump 18. The manner of the substrate being irradiated by the laser beam can be monitored by CCD camera 27 through a viewing window 26.

After the irradiation of the KrF excimer laser beam for 5 minutes, the heater temperature and the heater power control were not affected and the volume resistivity of the thin film was decreased to equal to or less than 5 Ωcm. The laser oscillation frequency was changed from 1 Hz to 100 Hz and found that the irradiation time becomes shorter as the oscillation frequency increases. Also, when the laser power is not more than 10W, a sufficiently low resistivity could not be obtained even after the irradiation for 3 hours, but with the substrate temperature elevated to 450° C., the volume resistivity was reduced to equal to or less than 5 Ωcm by the irradiation of within 15 minutes.

These thin films were observed with XD and found that the peaks of the provskite structure which was not observed before the laser beam irradiation appear and that the crystallization which usually takes place at a temperature equal to or more than 500° C. is realized. Also, it was found that there was no oxidization and damage due to melting in the wiring and the electrodes and that the TCR of the thin film for bolometer was equal to or more than 3%, which is sufficient to function as an infrared ray detector element.

While the sputtering and the laser beam irradiation has been described as being achieved within a gas atmosphere of 100% oxygen gas in the above fifth embodiment, similar results were obtained when other gases such as a mixture gas of oxygen and ozone, ozone gas, a mixture gas of oxygen and argon or a mixture gas of oxygen and nitrogen were used. Also, while the KrF excimer laser was used in the above embodiment, ArF laser or Co₂ laser has provided similar results. Further, the laser beam can be easily selectively applied only to the portion that is used as a bolometer by a lens or a mask, so that forming a pattern by the irradiation can be realized, so that it was possible to eliminate the patterning process by etching.

When the infrared ray detector element utilizing a bolometer of the oxide thin film having Bi₁₋ₓAₓMn₁O₃ (element A being at least one element selected from a rare earth metal or an alkaline earth metal, 0≦x<1) as a main component were formed by the sputtering and the heat treatment by heating the substrate by a heater, some did not satisfactorily function as an infrared detector element because the volume resistivity of the film was not decreased until the substrate temperature exceeds 500° C. As to Bi₁₋ₓAₓMn₁O₃, x was changed to determine the relationship between the composition and the substrate temperature at which a film that can be used as an infrared ray detector element is obtained. As a result of this, it was determined that, when x is equal to or less than 0.5, the substrate temperature must be equal to or more than 510° C. in order to function as an infrared ray detector element. Even under such circumstances, according to the present invention, by applying the heat treatment by an infrared ray irradiation or by a laser beam irradiation within an atmosphere of a gas containing oxygen or ozone, the volume resistivity of the thin film can be reduced to a level at which the thin film can be operated in an infrared ray detector circuit, whereby a bolometer thin film that satisfactorily functions as an infrared ray detector element can be obtained.

As has been described, according to the present invention, the method for manufacturing an infrared ray detector element utilizing a bolometer thin film having Bi₁₋ₓAₓMn₁O₃ (element A being at least one element selected from a rare earth metal or an alkaline earth metal, 0≦x<1) as a main component comprises a step of forming a thin film of an oxide having a metallic composition of Bi:A:Mn=1−x:X:1 by sputtering at a substrate temperature of equal to or above 100° C. and less than 500° C. within a gas atmosphere of containing oxygen or ozone, and a step of applying a heat treatment to the thin film of oxide within a gas atmoshpere containing oxygen or ozone to reduce the volume resistivity of the oxide thin film to a level at which an infrared ray detector circuit can operate, so that the bolometer thin film having Bi₁₋ₓAₓMn₁O₃ (element A being at least one element selected from a rare earth metal or an alkaline earth metal, 0≦x<1) as a main component can be functioned as a bolometer and that an infrared ray detector element of a high detectivity can be put in mass-production.

The oxide thin film may be laminated on a structure member which is an SiO₂ layer disposed on an Si substrate through an air gap or on an electrical insulator layer laminated on it, so that the thin film can be used as a bolometer that changes the resistance value depending upon the temperature change, and by providing an electrically insulating layer on the SiO₂ layer, the crystallization of Bi₁₋ₓAₓMn₁O₃ is promoted and the substrate temperature can be decreased.

The heat treatment applying to the oxide thin film may be achieved by an infrared ray or a laser irradiation, so that there is no need to heat the whole of the substrate, eliminating the chance of damaging the wiring and the electrode due to the oxidization or melting, and the volume resistivity of the thin film can be decreased to a level capable of allowing the operation in an infrared ray detector circuit, and the bolometer of the thin film having Bi₁₋ₓAₓMn₁O₃ (element A being at least one element selected from a rare earth metal or an alkaline earth metal, 0≦x<1) as a main component can be functioned as a bolometer and that an infrared ray detector element of a high detectivity can be put in mass-production. Further, the laser beam can be easily selectively applied to heat-treat a small portion corresponding to the electrode pattern, so that it is possible to eliminate the patterning process by etching.

The heat treatment applying to the oxide thin film may comprise a step of maintaining the oxide thin film at a temperature of 380° C.-450° C. for 10 min.-15 min., so that an infrared ray detector element utilizing a thin film material having a high temperature coefficient of resistance can be manufactured at a substrate temperature of equal to or less than 500° C., thus enabling the mass production of an infrared ray detector element utilizing a high detectivity bolometer.

The level of the volume resistivity of the oxide thin film at which the infrared ray detector circuit can operate may be equal to or more than 3.0 Ωcm, so that an infrared ray detector element utilizing a thin film material having a high temperature coefficient of resistance can be manufactured at a substrate temperature of equal to or less than 500° C., thus enabling the mass production of an infrared ray detector element utilizing a high detectivity bolometer.

What is claimed is:

1. A method for manufacturing an infrared ray detector element utilizing a bolometer having Bi₁₋ₓAₓMn₁O₃ (element A being at least one element selected from a rare earth metal or an alkaline earth metal, 0≦x<1) as a main component, the method comprising the steps of:
forming an oxide thin film having a metallic composition of Bi:A:Mn=1−x:X:1 by sputtering at a substrate temperature of equal to or above 100° C. and less than 500° C. within a gas atmosphere of containing oxygen or ozone; and
applying a heat treatment to said oxide thin film within a gas atmosphere containing oxygen or ozone to reduce the volume resistivity of said oxide thin film to a level at which an infrared ray detector circuit can operate.

2. The method for manufacturing an infrared ray detector element as claimed in claim 1, wherein said oxide thin film is laminated on a structure member which is an SiO₂ layer disposed on an Si substrate through an air gap or on an electrical insulator layer laminated thereon.

3. The method for manufacturing an infrared ray detector element as claimed in claim 1, wherein said heat treatment applying to said oxide thin film is achieved by an infrared ray or a laser irradiation.

4. The method for manufacturing an infrared ray detector element as claimed in claim 1, wherein said heat treatment applying to said oxide thin film comprises a step of maintaining said oxide thin film at a temperature of 380° C.-450° C. for 10 min.-15 min.

5. The method for manufacturing an infrared ray detector element as claimed in claim 1, wherein said level of the volume resistivity of said oxide thin film at which said infra-read ray detector circuit can operate is equal to or more than 3.0 Ωcm.
